(19) United States
(12) Patent Application Publication
(10) Pub. No.: US 2008/0265918 A1
(43) Pub. Date: Oct. 30, 2008

(54) Object-clamping lid subassembly of a test socket for testing electrical characteristics of an object

(75) Inventor: Gregg Wooden, Santa Clara, CA (US)

Correspondence Address: Greg Wooden;Protos Electronics, 1040 Di Giulio Avenue, # 200, Santa Clara, CA, 95050, US

(73) Assignee: Protos Electronics, Inc.

(21) Appl. No.: 11/789,103

(22) Filed: Apr. 24, 2007

(51) Int. Cl. G01R 31/02

(52) U.S. Cl. 324/754

(57) ABSTRACT

The test-socket lid subassembly of the invention consists of a lid for locking the object in the socket unit and a pusher with a handle for clamping the object in the locked position. The pusher is separated from the lid and is inserted into the lid for pressing on the object to fix the latter in the socket only after the lid is locked in place. The pusher is made in the form of a threaded ring, which has an outer thread for engagement with the inner thread in the central opening of the lid member for movement in the direction perpendicular to the contact surface of the object. This provides uniform distribution of pressure on the test object that is locked in the socket subassembly.

### FILED OF THE INVENTION

The present invention relates in general to the field of semiconductor product testing and, more particularly, to test sockets used for testing electrical characteristics of objects, e.g., for testing bump connectivity to bond pads in the manufacture of semiconductor chips. More specifically, the invention relates to a lid subassembly that is used in test sockets for locking a test object in a working position for testing and for supporting a pusher that applies clamping pressure to the test object during the test.

### BACKGROUND OF THE INVENTION

In manufacturing, all semiconductor devices pass through the following three essential stages: wafer fabrication, assembly of fabricated dies into semiconductor chips, and testing of semiconductor chips. The semiconductor chips are then incorporated into respective PC boards, and the assembled PC boards are also subjected to testing. The testing stage always includes evaluation of the electrical connections within the wafer, die, chip, and PC board. According to conventional practices, the semiconductor wafer is diced into individual semiconductor dies before testing and is then assembled into a chip or package. Individual testing does not take place until the dies have been packaged, therefore increasing the cost. This increased cost also results from the greater complexity, size, and quantity of the testing apparatus, as well as from the difficulty in manipulating large quantities of separately packaged dies.

Other problems associated with the technique of testing before assembling are increased expenses connected with tooling and labor costs, as well as increased waste that occur when defects are found in packages at a later time. Since in a conventional process all dies must be packaged before testing, this means that all defective dies will be packaged, and the expense of doing so is complete waste. For example, if 5%, a conservative estimate, of the dies fail either electrical or bum-in testing, that is five packaging operations that are wasted for every 100 dies that are produced. Thus, savings associated with wafer-level testing are realized because “good” dies can be identified during an earlier manufacturing stage, i.e., prior to packaging, and hence with lower losses when defective products are detected.

Several methods exist for the testing of bump integrity. These methods are described by Rajiv Roy and Tim Schafer (Rudolph Technologies Inc., Flanders, N.J.) in the article, “In-Process Bump Inspection”, Semiconductor International, Apr. 1, 2006 (http://www.reed-electronics.com/semiconductor/article/CA6319052) and are summarized as follows.

Backside Inspection—Backside inspection can provide useful information at this step. Sometimes, chemical residue left behind after etching migrates onto the wafer's backside. Any die with chemical residue on the backside will later adhere to the film frame—blue tape. When the die sorter tries to pick up the die, the die can crack. Additionally, backside inspection can detect particles that may cause “hot spots” in the lithography process. Without automated backside inspection, operations must include manual inspection of the backside of the wafers. If a defect is found, processing of the lot is paused, and the wafer is sent back to the fabrication process so that the chemical residue can be stripped off, contributing to the cost of the wafer. If an automated backside inspection system detects debris, the system marks the die so that the pick-and-place equipment ignores it, leaving it on the film frame.

Reflow—Reflow is the last step before the package is placed on the device. Heat is applied to the wafer to round off the bumps, creating a more uniform shape and enabling greater connectivity with the package. This is the most well known inspection step. Operations use 3-D bump inspection to check co-planarity of reflowed bumps on a die. Bumps that are outside the co-planarity threshold cause connectivity issues with the package. Bumps that are too tall push up the package, preventing shorter bumps from making a connection.

2-D bump Inspection—Before plating, advanced macro inspection can be used during polyimide patterning and base-layer metal to detect debris that can affect metal deposition or create adhesion defects. Equipment issues can also be detected by monitoring surface particles. 2-D bump inspection can measure CD lines to identify tolerances outside a specified parameter before the lines cause connectivity issues. Faulty wafers identified before plating can also be reworked.

3-D Bump Inspection—After plating, 2-D bump inspection can be used during electroplating and stripping to inspect CD lines and to measure diameters of the bumps. Bumps that are too tall or short will cause packaging issues. During stripping, advanced macro and 2-D and 3-D bump inspections can be used. A 2-D bump inspection can measure the height of a bump and can detect bridge bumps. A 3-D bump inspection can measure height, co-planarity, and morphology of a bump in order to identify defects that can cause connectivity issues with the package. Advanced macro inspection can detect surface particles to measure the effectiveness of the stripping process.

A 2-D bump inspection can be used as a process monitor at the base-layer metal to detect residual metal or acid or to ensure that CD lines are within tolerances. A 3-D bump inspection can also serve as a process monitor, detecting excess debris or measuring the height of a bump in order to ensure solid connectivity with the package. Backside inspection can also be used to find chemical residue that can cause a die to crack when the die is picked off the film frame or to find particles that can cause hot-spot anomalies during lithography.

A 3-D bump inspection can check the co-planarity of bumps during reflow, thereby detecting bumps that can cause connectivity issues with the package and measuring the effectiveness of the process.

Advanced macro inspection, 2-D and 3-D bump inspections, and backside inspection provide valuable data for process engineers. The particular mix of inspection technologies described here will vary from process to process. Inspections play a vital role in process development and process control. In process development, inspections provide feedback needed by the engineers in order to fine-tune a process and to achieve higher production yields. During process control, inspections detect process excursions and aid in the diagnosis of the root cause. Early detection and correction are especially important for bump processes because completed wafers result in very expensive scrap. By accelerating the process development cycle and shortening the time required to detect and recover from yield excursions, bump inspection can contribute dramatically to process profitability.

However, all methods described above have a common disadvantage, i.e., they are based on information collected by optical means such as bump height and co-planarity, as well as defects such as misplaced bumps, deformed bumps, bridged bumps, shear bumps, extra satellites, missing metals, CDs, excess resists, particles, cracks, scumming, chemical residues, etc. The results of the indirect control methods are then extrapolated into conditions of electrical contact between the bumps and the supporting substrate surfaces.

In an attempt to solve the problems of the prior art, the applicant has developed an improved bump connectivity test socket that is able to test connectivity or integrity of a plurality of bumps formed on a semiconductor wafer by directly measuring contact conditions on the interface between the bump and the wafer or a semiconductor die. This apparatus and method are disclosed in pending U.S. patent application Ser. No. 11/490,276 filed by the same applicant on Jul. 21, 2006.

In the aforementioned test socket, the contact conditions on the interface between the plurality of bumps and the surface of a wafer or a semiconductor die are measured by forming parts of a plurality of individual oscillation circuits that include the conductive elements of individual pogo pins and bumps between a common electrode and a multiple-channeled measurement system.

The test socket of U.S. patent application Ser. No. 11/490,276 is shown in FIG. 1A, which is a general three-dimensional view of the device shown in the form of a lid-socket assembly for retaining electronic devices, e.g., IC chips, in a fixed position for testing their properties. The assembly consists of a socket subassembly 20 and a lid subassembly 22 that can be attached to the socket subassembly 20 by means of a locking mechanism (not shown in FIG. 1A). Furthermore, the lid subassembly 22 supports a pusher 24, only a heat-sink portion 25 of which is seen in FIG. 1A. The lid subassembly is shown in a closed state.

For attachment of the lid subassembly 22, which will be described later, the socket body 28 has on its upper face openings 44a, 44b, etc., for locking the spherical ends of spring plungers (not shown in FIG. 1A) which are located on the mating side of the lid subassembly 22. The plungers are screwed into a frame 50 of the lid subassembly 22 so that the spherical ends of the plungers project from the lower side of the frame 50 in order to lock into the respective openings 44a, 44b, etc., on the upper face of the socket body 28.

As shown in FIG. 1A, the lid subassembly 22 consists of the aforementioned rectangular frame 50 and a lid member 60 that is pivotally connected on pins such as a pin 61, which is the only one seen in FIG. 1A. These pins are inserted into openings of the frame 50 and an opening in the lid member 60 for pivotal connection of the lid member to the frame 50. As a result, the lid member 60 can be turned up relative to the frame 50 to provide access to the recess of the socket body 28 for inserting an object, e.g., an IC chip (not shown) that has to be tested, or for turning the lid member 60 down for clamping the IC chip in the position for testing.

A disadvantage of such a construction is that the pusher 24 that applies clamping pressure to the test object is secured in the lid member 60 and participates in pivotal motion of the lid member 60 relative to the lid frame 50. The pivotal movement of the pusher 24 relative to the test object can create non-uniform distribution of the clamping pressure with the difference in pressure applied to the side of the pusher that is closest to the pivotal axis and the side that is farthest from the pivot axis. In order to compensate for these non-uniformities, the test socket of U.S. patent application Ser. No. 11/490,276 has a system of spring-loaded elements that provides the pusher with self-alignment features with five degrees of freedom. This makes the construction complicated in design and assembly and expensive in manufacturing.

### SUMMARY OF THE INVENTION

It is an object of the present invention to provide a lid subassembly that is intended for use in testing electrical characteristics of contats, e.g., in a bump connectivity test socket for testing electronic devices such as IC chips, and that is simple in construction and assembly, inexpensive to manufacture, and provides uniform application of pressure from the pusher to the object without the use of complicated self-alignment means. It is another object of the invention to provide a test socket lid subassembly in which a pusher is separated from the lid subassembly during pivotal movement of the latter. It is another object to provide a test socket of the aforementioned type wherein the pusher is connected to a rotating handle and is inserted into the lid subassembly in the direction perpendicular to the pressure-receiving surface of the test object after the lid is fixed in an object-locking position.

The test-socket lid subassembly of the invention consists of two separated main parts, i.e., a lid for locking the object in the socket unit and a pusher with a handle for clamping the object in the locked position. Similar to a conventional device, one end of the lid member has a pivotal connection to the lid frame, while the opposite end of the lid member pivotally supports a latch with an L-shaped latching member that can be turned and locked in the recesses on the edge of the lid frame for locking the lid to the frame. However, in contrast to the previously described known lid subassembly, the pusher is separated from the lid and is inserted into the lid for pressing on the object in order to fix the latter in the socket only after the lid is locked in place. The pusher is made in the form of a threaded ring, which has an outer thread on its periphery and is rigidly attached to a substantially circular handle, which has a projecting lobe for convenience in gripping. On the other hand, the lid member has a central opening with an inner thread for engagement with the thread ring so that the thread ring can be screwed into the threaded opening of the lid member for movement in the direction perpendicular to the contact surface of the object, which is locked in the socket subassembly. The axial movement of the thread ring is continued until the lower end-face thereof comes into contact with the aforementioned contact surface of the object.

For alignment of the object, e.g., an IC chip, in the socket and relative to the pusher, the device is provided with a frame-like pusher clamp which is attached to the lower side of the lid member through a spring-loaded connection, is fitted in the locked position of the lid onto the IC chip, and presses with its lower end-face on the peripheral edges on the chip. The pusher clamp has a central opening for guiding the thread ring when the latter is threaded into the threaded opening of the lid member and is moved towards the object.

When the handle rotates together with the thread ring relative to the lid member, its lobe, which projects in the radial outward direction, also turns, and when movement of the thread ring, and hence, of the handle is stopped because of contact of the end face of the thread ring with the object, the aforementioned lobe is positioned just above the latch. As a result, the latch is interlocked in the locked position and cannot be accidentally unlocked until the thread ring is untwisted from the object clamping position. In other words, when the object is clamped, the lid cannot be accidentally opened.

Since IC chips may have different heights, the device of the invention has a feature that allows adjustment of the vertical stroke of the pusher relative to the object. This is achieved by forming a plurality of circumferentially arranged threaded openings on the upper end-face of the thread ring, while the handle has a plurality of openings for inserting the screws that attach the handle to the thread ring. By locking the handle in different positions with respect to the beginning of the thread grooves on the outer surface of the thread ring, it becomes possible to adjust the total angle of rotation of the pusher relative to the lid member from the beginning of the rotation to the moment of contact of the pusher with the object.

Furthermore, the angular movement of the handle and hence of the pusher relative to the lid is limited by means of an arched slot formed on the lower end-face of the handle and a pin that projects from the mating surface of the lid member and slides in the aforementioned slot. This pin may be made in the form of a spring plunger that snaps into the recess on the bottom of the arched groove for locking the handle in the selected angular position.

The entire lid subassembly can be attached to a socket unit in the same manner as a conventional device. The construction of this attachment is beyond the scope of the present invention and therefore description thereof is omitted from the present application.

### BRIEF DESCRIPTION OF THE DRAWINGS

FIG. 1A is a general three-dimensional view of a known lid-socket assembly.

FIG. 1B is a general three-dimensional view of a lid-socket assembly of the invention.

FIG. 1C is a bottom view of the lid subassembly of the invention.

FIG. 2 is a side view of the lid subassembly with the lid member in the open position for insertion of a test object.

FIG. 3 is an exploded three-dimensional view of the lid subassembly of the invention.

FIG. 4 is a side view illustrating the lid member in the locked position on the lid frame and the handle with the thread ring screwed into the lid frame.

FIG. 5 is a view of the lower side of the handle of the lid subassembly of the invention.

FIG. 6 is a top view of the handle of the lid subassembly of the invention.

### DETAILED DESCRIPTION OF THE PREFERRED EMBODIMENT

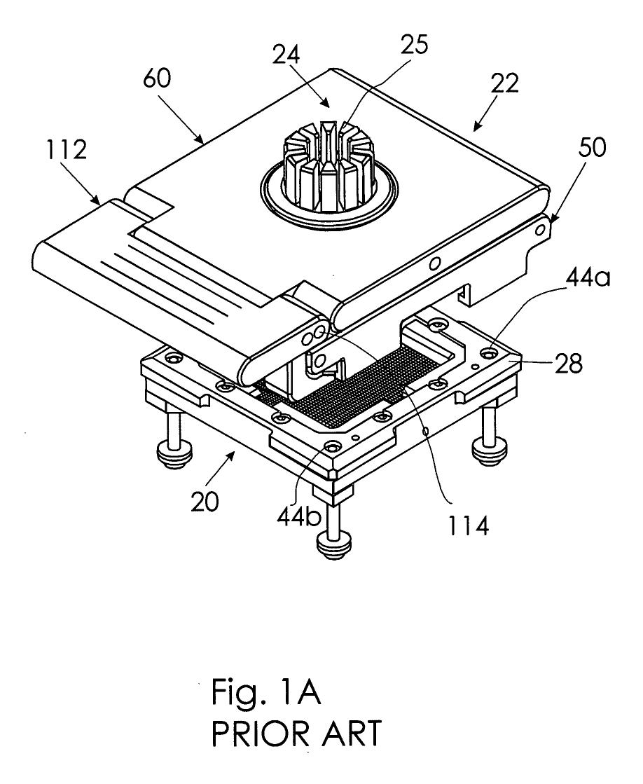

A general three-dimensional view of the test-socket lid subassembly of the invention in the closed position is shown in FIG. 1B. The lid subassembly, which as a whole is designated by reference numeral 100, consists of two separated main parts, i.e., a lid 102 for locking the object in the socket unit 103 and a pusher 124 with a handle 106 for clamping the object in the locked position. FIG. 1C is a bottom view of the lid subassembly.

Similar to the above-described device of U.S. patent application Ser. No. 11/490,276, the lid subassembly has a lid member 108, one end of which is pivotally connected to a lid frame 110 with rotation around a transverse axle 111, while the opposite end of the lid member 108 (FIG. 1B) pivotally supports a latch 112 that can be turned on an axle 114 and locked around the outer rings of the bearings 107 and 109 (FIG. 1C) installed on the edge of the lid frame 110 for locking the lid member 108 to the frame 110. For this purpose, the latch 112 is provided with L-shaped projections 116a and 116b (FIG. 1C), which in a locked position of the lid engage correspondingly shaped recesses 118. Only one L-shaped projection 116 and only one recess 118 can be seen in FIG. 1B.

As in a conventional device, the lid sub-unit is attached to a socket unit 121 (FIG. 1B) of the lid-socket assembly. The pogo pins, elements of the electric circuit, measurement instruments, and other parts and units which are associated with testing of electric connectivity of the IC chips, are not shown in the drawing, and description thereof is omitted since these units, parts, and elements are beyond the scope of the present invention. The structure of the socket unit 121 is also omitted from the present description since the socket unit 121 is the same as one described in U.S. patent application Ser. No. 11/490,276.

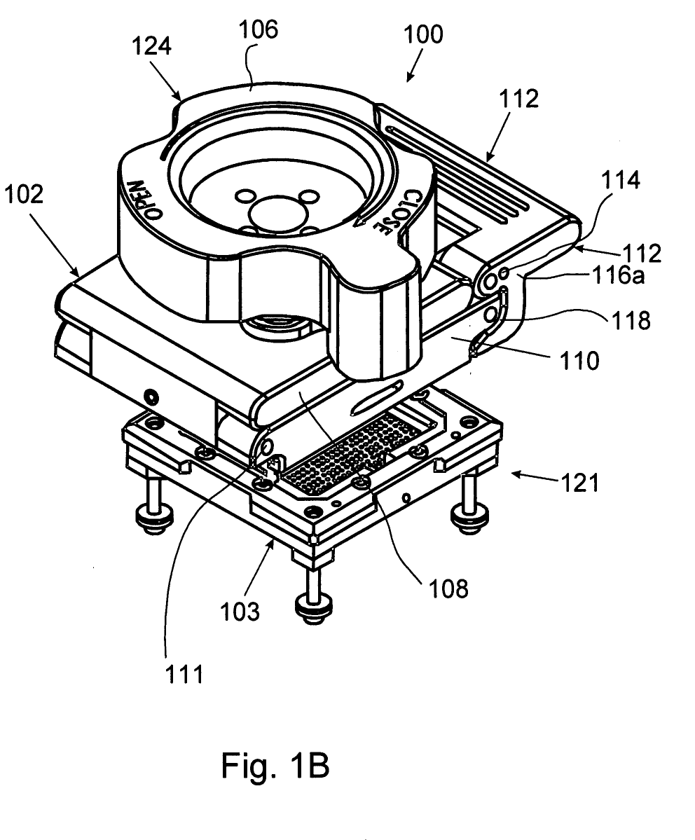

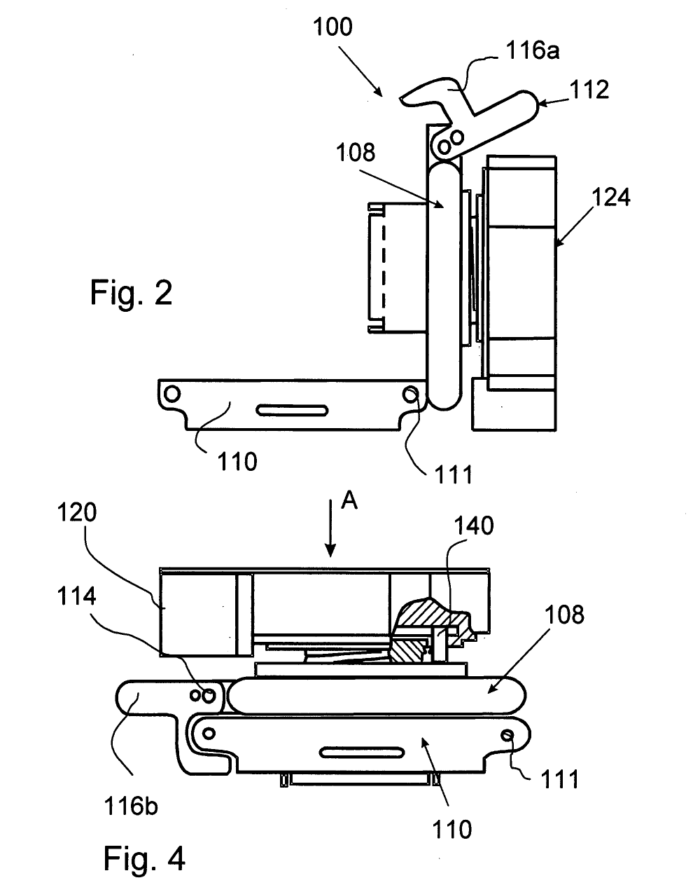

Nevertheless, in order to insert the test object, e.g., an IC chip (not shown), into the socket 121 to which the lid subassembly 100 is to be attached, the lid member 108 must be opened and pivotally turned relative to the lid frame 110 to the position shown in FIG. 2, which is a side view of the lid subassembly 100. This position of the lid member 108 provides access to the socket 121 so that a test object can be inserted and placed into working position in the socket 121. After insertion of the object into the socket, the lid member 108 can be returned to the position shown in FIG. 1 B and locked by means of the latch 112. FIG. 4 is a side view of the lid subassembly in the closed and locked position of the lid member 108.

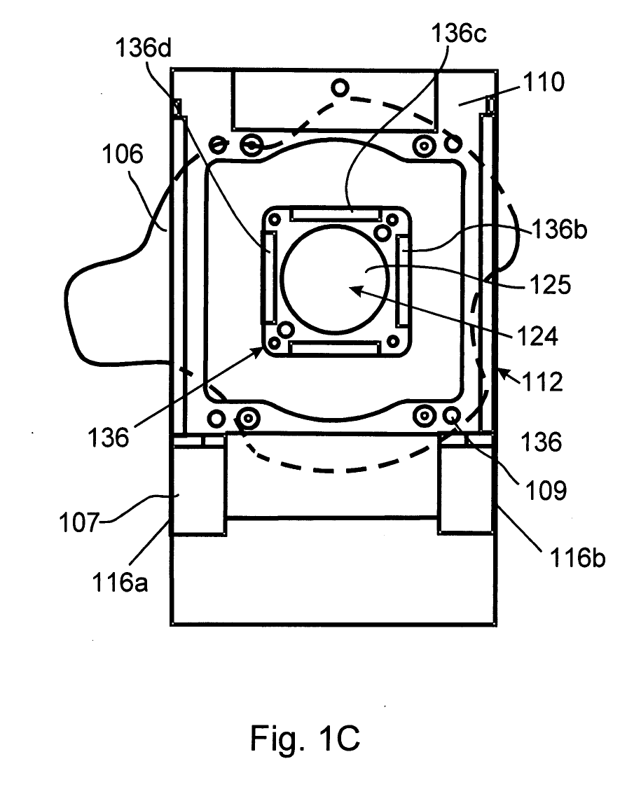

The structure of the entire lid subassembly 100 is shown in more detail in FIG. 3, which is an exploded three-dimensional view of the lid subassembly 100. It can be seen from this drawing that the handle 106 has a substantially circular shape and is provided with a lobe 120 which projects radially outward from the periphery of the round handle. This lobe 120 makes it possible to conveniently grip the handle for turning and also to fulfill the interlocking function for the latch 112, which will be described later.

Reference numeral 124 designates a cylindrical pusher in the form of a thread ring that applies pressure to a test object when the latter is locked in the socket 121 (FIG. 1B) in an aligned position for testing. Hereinafter, the pusher will be referred to as a thread ring 124. The thread ring 124 is rigidly attached to the handle 106 by screws 126a, 126b, 126c, and 126d, which are screwed into threaded openings selected from a plurality of openings 128a through 128n formed on the upper end-face of the thread ring 124 (FIG. 3). The thread ring 124 has an external thread 130 that engages the inner thread 132 formed in the central opening 134 of the lid member 108. In FIG. 1C and FIG. 3, reference numeral 136 designates a pusher clamp (FIG. 1C and FIG. 3), which is made in the form of a rigid frame attached to the lid member 108 through spring-loaded means and intended for fitting on the IC chip inserted into the socket 121 (FIG. 1B) for fixing the IC chip in the measurement position by resting with its lower edges 136a, 136b, 136c, and 136d (FIG. 1C) on the edges of the IC chip. The aforementioned spring-loaded means that connect the pusher clamp 136 to the lid member 108 comprises a group of bolts 109a, 109b, 109c, and 109d. The threaded ends of the bolts 109a, 109b, 109c, and 109d are screwed into respective threaded openings of the pusher clamp 136 (only two of these openings 113c and 113d are seen in FIG. 3). Helical springs 115a, 115b, 115c, and 115d are placed between the heads of the respective bolts 109a, 109b, 109c, and 109d and recesses formed in the upper side of the lid member 108 (only three such recesses 117a, 117c, and 117d are seen in FIG. 3). As a result, the springs 115a, 115b, 115c, and 115d allow spring-loaded movement of the pusher clamp 136 relative to the lid member 108. This movement, in turn, allows raising of the pusher clamp 136 from the object when the test is completed, and the handle 106 with the thread ring 124 is untwisted from the clamping position.

In contrast to the previously described known lid subassembly, the thread ring 124, i.e, the pusher, is separated from the lid member 108 and its frame 110, and is inserted into the lid for pressing on the object in order to fix the latter in the socket 121 (FIG. 1B) only after the lid member 108 is locked in place by the latch 112. Another essential distinction from the known lid subassembly is that the pusher, i.e., the thread ring 124, moves relative to the object in the direction A (FIG. 4) perpendicular to the contact surface of the object locked in the socket subassembly until the lower end face 125 (FIG. 1C) of the thread ring 124 comes into contact with the aforementioned contact surface of the object.

When the handle 106 is turned together with the thread ring 124 relative to the lid member 108, its lobe 120, which projects in the radial outward direction, also turns. The angle of rotation of the handle 106 and of the thread ring 124 is selected so that when the pusher comes into contact with the object and rotation is stopped, the aforementioned lobe 120 is positioned just above the L-shaped latch 112. This position is shown in FIG. 4. As a result, the latch 112 is interlocked in the locked position and cannot be accidentally unlocked until the thread ring 124 is untwisted from the object clamping position. In other words, when the object is clamped, the lid member 108 cannot be accidentally opened.

Since IC chips may have different heights, the device of the invention has a feature that allows adjustment of the vertical stroke of thread ring 124 relative to the object. This is achieved by using the aforementioned screws 126a, 126b, 126c, and 126d and threaded openings 128a through 128n formed on the upper end-face of the thread ring 124 to attach the handle 106 in different positions with respect to the beginning of the thread grooves 130 on the outer surface of the thread ring 124 (FIG. 3). As a result, it becomes possible to adjust the total angle of rotation of the thread ring 124 relative to the lid member 108 from the beginning of the rotation to contact of the end face 125 of the thread ring 124 with the object.

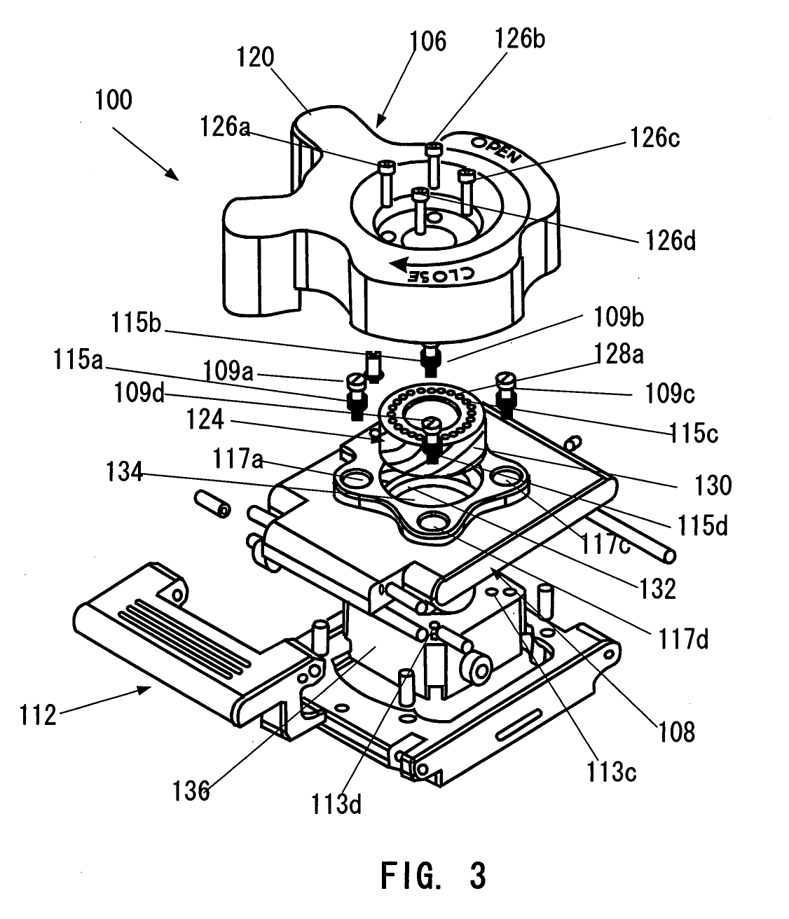

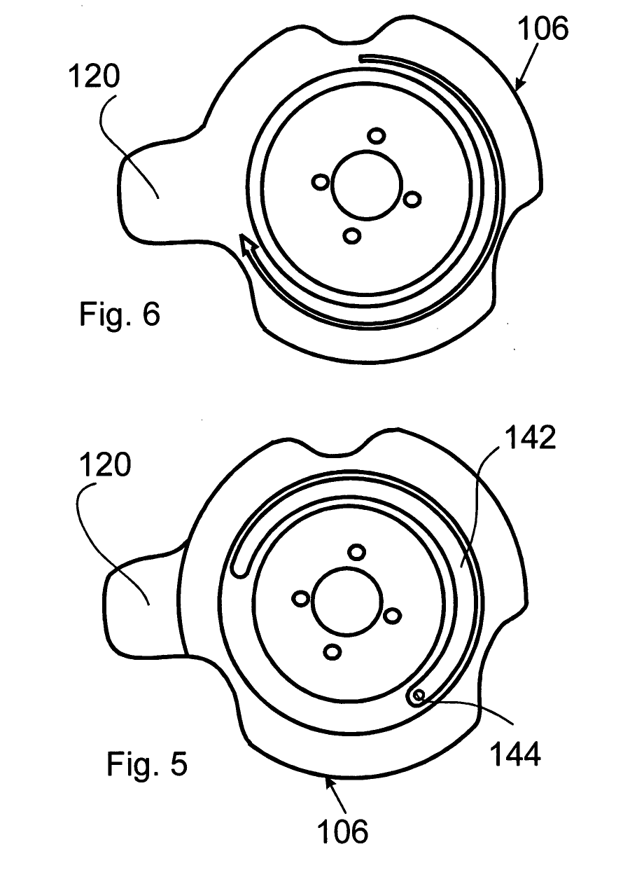

Furthermore, the angular movement of the handle 106 and hence of the pusher relative to the lid member 108 is limited by means of an arched slot 142 formed on the lower end-face of the handle 106 and a pin 140 that projects from the mating surface of the lid member 108 and is inserted into the aforementioned slot 142. The pin 140 and the slot are shown in FIG. 4, which is a side view of the device illustrating the lid member 106 in the locked position on the lid frame 110. In FIG. 1B the handle 106 is shown in the position with the thread screw 124 screwed into the threaded opening 134 (FIG. 3) of the lid member 108. The arched slot 142 is shown in FIG. 5, which is a view of the lower side of the handle 106, and FIG. 6 is a top view of the handle 106. The pin 140 may be made in the form of a spring plunger that snaps into the recess 144 on the bottom of the arched groove 142 to lock the handle 106 in the selected angular position.

The entire lid subassembly can be attached to the socket unit 121 (FIG. 1B) in the same manner as a conventional device. Construction of the socket and attachment thereto is beyond the scope of the present invention.

Thus, it has been shown that the invention provides a lid subassembly that is intended for use in a bump connectivity test socket for testing electronic devices such as IC chips and which is simple in construction and assembly, inexpensive to manufacture, provides uniform application of pressure from the pusher to the object without the use of complicated self-alignment means, and has a pusher separated from the lid subassembly during pivotal movement of the latter and which can be inserted into the lid subassembly in the direction perpendicular to the pressure-receiving surface of the test object after the lid is fixed in the object-locking position.

Although the invention has been shown and described with reference to specific embodiments, it is understood that these embodiments should not be construed as limiting the areas of application of the invention and that any changes and modifications are possible, provided these changes and modifications do not depart from the scope of the attached patent claims. For example, the handle may have a shape different from the one shown in the drawings and may be made from a single piece of material with the threaded pusher. The pin may be installed on the lower end-face of the handle, while the arched slot can be formed on the upper surface of the lid member. Depending on the shape of the IC chip, the pusher clamp may have a round, triangular, rectangular, or any other required shape. Although the description refers to bumps, this can be any contact feature of the integrated circuit.

1. (canceled)

2. (canceled)

3. (canceled)

4. (canceled)

5. (canceled)

6. (canceled)

7. (canceled)

8. (canceled)

9. (canceled)

10. (canceled)

11. An object-clamping lid subassembly of a test socket for testing electrical characteristics of an object comprising:
a lid that includes a lid frame having a first side and a second side opposite to the first side; a lid member that has a central opening with an inner thread and that is pivotally connected to the first side of the lid frame with the possibility of rotation between the open position for insertion of an object to a testing position in the test socket and the closed position; and a locking member attached to the aforementioned second side of the lid frame for locking the lid member relative to the lid frame in the aforementioned closed position; and
a pusher that can be completely disconnected from the lid and that comprises a thread ring which has an outer thread which can be engaged with the aforementioned inner thread of the lid member that applies pressure to the object in the testing position of the object when the thread ring is screwed into the aforementioned threaded opening and moves in the direction perpendicular to the test object, wherein the thread ring pusher is provided with a handle that is rigidly connected thereto, and wherein the thread ring is provided with means for alignment of the test object and for locking the object in the test position;
the aforementioned means for alignment of the test object and for locking the object in the test position comprising a pusher clamp which is connected to the lid member by a connection means and which has a central opening for passing of the thread ring to the test object and lower edges for pressing on the test object.

12. The object-clamping lid subassembly of claim 11, wherein the aforementioned connection means comprise a spring-loaded connection that allows movement of the pusher clamp relative to the lid member.

13. The object-clamping lid subassembly of claim 4, wherein the means for alignment of the test object and for locking the object in the test position comprise a pusher clamp which is connected to the lid member by a connection means and which has a central opening for passing of the thread ring to the test object and lower edges for pressing on the test object.

14. The object-clamping lid subassembly of claim 13, wherein the aforementioned connection means comprise a spring-loaded connection that allows movement of the pusher clamp relative to the lid member.

15. The object-clamping lid subassembly of claim 5, wherein the means for alignment of the test object and for locking the object in a test position comprise a pusher clamp which is connected to the lid member by a connection means and which has a central opening for passing of the thread ring to the test object and lower edges for pressing on the test object.

16. The object-clamping lid subassembly of claim 15, wherein the aforementioned connection means comprise a spring-loaded connection that allows movement of the pusher clamp relative to the lid member.

17. The object-clamping lid subassembly of claim 6, wherein the means for alignment of the test object and for locking the object in a test position comprise a pusher clamp which is connected to the lid member by a connection means and which has a central opening for passing of the thread ring to the test object and lower edges for pressing on the test object.

18. The object-clamping lid subassembly of claim 17, wherein the aforementioned connection means comprise a spring-loaded connection that allows movement of the pusher clamp relative to the lid member.

19. The object-clamping lid subassembly of claim 11, wherein the handle has means for adjusting the angular position of the handle relative to the outer thread of the thread ring when the handle is connected to the thread ring, said means for adjusting the angular position of the handle relative to the outer thread of the thread ring comprising a plurality of threaded openings in the thread ring, at least two openings in the handle, and at least two screws that can be threaded into selected openings of said plurality through said at least two openings in the handle.

20. The object-clamping lid subassembly of claim 12, wherein the handle has means for adjusting the angular position of the handle relative to the outer thread of the thread ring when the handle is connected to the thread ring, said means for adjusting the angular position of the handle relative to the outer thread of the thread ring comprising a plurality of threaded openings in the thread ring, at least two openings in the handle, and at least two screws that can be threaded into selected openings of said plurality through said at least two openings in the handle.
